(19) United States
(12) Patent Application Publication
(10) Pub. No.: US 2016/0141182 A1
(43) Pub. Date: May 19, 2016

(54) SLURRY COMPOSITIONS AND METHODS OF FABRICATING SEMICONDUCTOR DEVICES USING THE SAME

(71) Applicant: Samsung Electronics Co., Ltd., Suwon-si (KR)

(72) Inventors: Sangkyun Kim, Hwaseong-si (KR); Yun-Jeong Kim, Suwon-si (KR); Sanghyun Park, Hwaseong-si (KR); Se Jung Park, Hwaseong-si (KR); Bo Hyeok Choi, Yongin-si (KR)

(21) Appl. No.: 14/886,161

(22) Filed: Oct. 19, 2015

(30) Foreign Application Priority Data
Nov. 14, 2014 (KR) 10-2014-0159059

(51) Int. Cl. H01L 21/308; H01L 21/304; C09G 1/02

(52) U.S. Cl. CPC H01L 21/308; C09G 1/02; H01L 21/304

(57) ABSTRACT

Provided are slurry compositions for polishing a germanium-containing layer and methods of fabricating a semiconductor device using the same. The slurry composition may include a polishing particle, an oxidizing agent, a polishing accelerator, and a selectivity control agent. The oxidizing agent may include at least one selected from the group consisting of superoxide, dioxygenyl, ozone, ozonide, chlorite, chlorate, perchlorate, halogen compounds, nitric acid, nitrate, hypochlorite, hypohalite, and peroxide.

### CROSS-REFERENCE TO RELATED APPLICATIONS

This U.S. non-provisional patent application claims priority under 35 U.S.C. §119 to Korean Patent Application No. 10-2014-0159059, filed on Nov. 14, 2014, in the Korean Intellectual Property Office, the entire contents of which are hereby incorporated herein by reference.

### FIELD

The present disclosure relates to slurry compositions and methods of fabricating semiconductor devices with PMOS and NMOS transistors using the same.

### BACKGROUND

Due to their small-size, multifunctionality, and/or low-cost characteristics, semiconductor devices are considered important elements in the electronic industry. Semiconductor devices can generally be classified into a memory device for storing data, a logic device for processing data, and a hybrid device capable of performing various functions.

There is an increasing demand for a semiconductor device with a higher integration density and higher performance. Although a variety of studies are being conducted to meet such a demand, it is necessary to reduce a process margin (for example, in a photolithography process) and this may lead to several difficulties in fabricating a semiconductor device.

### SUMMARY

Example embodiments of the present inventive concepts provide a slurry composition, which may allow for a polishing process to be effectively used in the fabrication of a highly-integrated semiconductor device.

Other example embodiments of the present inventive concepts provide a method of fabricating a highly-integrated semiconductor device.

According to example embodiments of the present inventive concepts, a slurry composition for polishing a germanium-containing layer may include a polishing particle; an oxidizing agent including at least one selected from the group consisting of superoxide, dioxygenyl, ozone, ozonide, chlorite, chlorate, perchlorate, halogen compounds, nitric acid, nitrate, hypochlorite, hypohalite, and peroxide; a polishing accelerator; and a selectivity control agent.

In example embodiments, the polishing particle may include at least one of silica (SiO₂), ceria (CeO₂), or aluminum (Al₂O₃).

In example embodiments, the polishing particle may have a size ranging from 30 nm to 80 nm.

In example embodiments, the polishing accelerator may include an organic acid.

In example embodiments, the polishing accelerator may include at least one selected the group consisting of acetic acid, citric acid, formic acid, gluconic acid, lactic acid, oxalic acid, tartaric acid, and carboxylic acid.

In example embodiments, the selectivity control agent may include a material allowing the germanium-containing layer to have a higher polishing rate than that of a layer containing at least one of silicon, oxide, and nitride.

In example embodiments, the selectivity control agent may include at least one of pyrrolidone-based polymers, glycol-based polymers, oxide-based polymers, or acrylate-based polymers.

In example embodiments, the selectivity control agent may include at least one of poly(vinylpyrrolidone) (PVP) and polyethylene glycol (PEG), when the germanium-containing layer is polished along with a silicon-containing layer.

In example embodiments, the selectivity control agent may include poly(ethylene oxide) (PEO), when the germanium-containing layer is polished along with an oxide-containing layer.

In example embodiments, the selectivity control agent may include poly(acrylic acid) (PAA), when the germanium-containing layer is polished along with a nitride-containing layer.

In example embodiments, the slurry composition may further include a pH modifier.

In example embodiments, the slurry composition may have a pH value ranging from 3 to 7.

In example embodiments, the pH modifier may include at least one of nitric acid, sulfuric acid, hydrochloric acid, and acetic acid.

According to example embodiments of the present inventive concepts, a method of fabricating a semiconductor device may include forming a silicon-containing NMOS region and a germanium-containing PMOS region on a silicon-containing substrate, and polishing the germanium-containing PMOS region using a slurry composition to have a top surface coplanar with that of the silicon-containing NMOS region. The slurry composition may include a polishing particle, an oxidizing agent including at least one selected from the group consisting of superoxide, dioxygenyl, ozone, ozonide, chlorite, chlorate, perchlorate, halogen compounds, nitric acid, nitrate, hypochlorite, hypohalite, and peroxide, a polishing accelerator, and a selectivity control agent.

In example embodiments, the forming of the silicon-containing NMOS region and the germanium-containing PMOS region on the silicon-containing substrate may include forming a mask pattern on a silicon-containing initial substrate, etching the silicon-containing initial substrate using the mask pattern to form a recess, and forming the germanium-containing PMOS region to fill the recess.

According to example embodiments of the present inventive concepts, a composition may be provided. The composition may include a polishing particle; an oxidizing agent; a polishing accelerator; and a selectivity control agent, and the composition may be in the form of a slurry and have a pH value in a range of 3 to 7.

In example embodiments, the polishing particle may have a size in a range of 30 nm to 80 nm.

In example embodiments, the polishing accelerator may be an organic acid.

In example embodiments, the selectivity control agent may be selected from the group consisting of poly(vinylpyrrolidone) (PVP), polyethylene glycol, (PEG), poly(ethylene oxide) (PEQ), poly(acrylic acid) (PAA), and any combination thereof.

In example embodiments, the composition, when used in a polishing process, may provide a polishing rate for a germanium-containing layer in a range of about 1,600 Å/min to about 3,000 Å/min, and/or any range and/or individual value therein, and/or a polishing rate for a layer containing silicon, oxide, and/or nitride in a range of about 10 Å/min to about 50 Å/min, and/or any range and/or individual value therein.

### BRIEF DESCRIPTION OF THE DRAWINGS

The above and other aspects, features and advantages of the present inventive concepts will become more apparent in view of the attached drawings and accompanying detailed description. The drawings provided herein represent non-limiting, example embodiments according to various embodiments of the present inventive concepts.

FIG. 1 is a sectional view schematically illustrating a chemical mechanical polishing apparatus according to various embodiments of the present inventive concepts.

FIGS. 2A through 9A are perspective views illustrating a method of fabricating a semiconductor device, according to example embodiments of the present inventive concepts.

FIGS. 2B through 9B are sectional views taken along lines I-I′ of FIGS. 2A through 9A, respectively, according to various embodiments of the present inventive concepts.

FIGS. 2C through 9C are sectional views taken along lines II-II′ of FIGS. 2A through 9A, respectively, according to various embodiments of the present inventive concepts.

FIGS. 10A and 10B are graphs showing a change in weight for first and second wafers after the first and second wafers were dipped into slurry compositions having different pH values according to various embodiments of the present inventive concepts.

FIGS. 11A and 11B are graphs showing reduction potentials for germanium and germanium-silicon according to pH values of slurry compositions according to various embodiments of the present inventive concepts.

FIGS. 12A and 12B are images showing the surface roughness of a wafer on which a silicon-germanium layer was formed according to various embodiments of the present inventive concepts.

FIGS. 13A and 13B are images showing surface roughness of a wafer on which a polishing process has been performed using the slurry composition according to various embodiments of the present inventive concepts.

It should be noted that these figures are intended to illustrate the general characteristics of methods, structures and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments are described below with reference to the accompanying drawings. Many different forms and embodiments are possible without deviating from the spirit and teachings of this disclosure and so the disclosure should not be construed as limited to the example embodiments set forth herein. Rather, these example embodiments are provided so that this disclosure will be thorough and complete, and will convey the scope of the disclosure to those skilled in the art. In the drawings, the sizes and relative sizes of layers and regions may be exaggerated for clarity. Like reference numbers refer to like elements throughout the description.

The terminology used herein is for the purpose of describing particular embodiments only and is not intended to be limiting of the embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein the term “and/or” includes any and all combinations of one or more of the associated listed items.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein may be interpreted accordingly.

Example embodiments of the present inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the present inventive concepts should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of example embodiments.

It will be understood that although the terms “first,” “second,” etc. may be used herein to describe various elements, these elements should not be limited by these terms. These terms are only used to distinguish one element from another. Thus, a “first” element could be termed a “second” element without departing from the teachings of the present embodiments.

Unless otherwise defined, all terms (including technical and scientific terms) used herein have the same meaning as commonly understood by one of ordinary skill in the art to which this present inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

According to example embodiments of the present inventive concepts, a slurry composition may be configured to provide a high polishing rate on a material containing germanium (Ge) or silicon germanium (SiGe). According to some aspects of the present inventive concepts, the slurry composition may be configured to have the ability to polish a Ge- or SiGe-containing layer with a high polishing rate with respect to other materials (e.g., silicon, oxide, or nitride).

The slurry composition may include a polishing particle, an oxidizing agent, an polishing accelerator, and/or a selectivity control agent. In some embodiments, the slurry composition may further include a solvent, such as, for example water.

The polishing particle may include a material having a higher polishing rate on a germanium (Ge) and/or silicon-germanium (SiGe) layer than that on a silicon, oxide and/or nitride layer. The polishing particle may include at least one of silica (SiO₂), ceria (CeO₂), alumina (Al₂O₃), and any combination thereof. In some embodiments, the polishing particle may be provided in a colloidal, fumed, or calcination shape. According to some aspects of the present inventive concepts, the polishing particle may contain colloidal silica, and the use of the colloidal silica may make it possible to suppress defects from occurring in a to-be-polished layer during a polishing process and consequently to improve flatness of the to-be-polished layer. In some embodiments, a slurry composition may include a polishing particle in a range of about 0.1% to about 5% by weight of the composition and/or any range and/or individual value therein, such as, for example, about 0.1% to about 3% or about 0.5% to about 2% by weight of the composition.

The polishing particle may have a size in a range of about 30 nm to about 80 nm. In the case where the size of the polishing particle is smaller than 30 nm, there may be difficulty in performing a mechanical polishing effectively, whereas in the case where the size of the polishing particle is greater than 80 nm, the germanium and/or silicon germanium layer may be damaged during the polishing process.

The oxidizing agent may oxidize the germanium (Ge) layer and/or the silicon-germanium (SiGe) layer. The oxidizing agent may be a strong oxidizing agent, and may contain at least one of inorganic acid- and organic acid-based oxidizing materials. The oxidizing agent may include at least one selected from the group consisting of superoxide, dioxygenyl, ozone, ozonide, chlorite, chlorate, perchlorate, halogen compounds, nitric acid, nitrate, hypochlorite, hypohalite, peroxide, and any combination thereof. In some embodiments, a slurry composition may include an oxidizing agent in a range of about 0.1% to about 1% by weight of the composition and/or any range and/or individual value therein, such as, for example, about 0.1% to about 0.5% or about 0.25% to about 0.75% by weight of the composition.

The polishing accelerator may increase a polishing rate of the germanium (Ge) layer and/or the silicon-germanium (SiGe) layer. The polishing accelerator may contain at least one organic acid material. For example, the polishing accelerator may include at least one selected from the group consisting of acetic acid, citric acid, formic acid, gluconic acid, lactic acid, oxalic acid, tartaric acid, carboxylic acid, and any combination thereof. In some embodiments, a slurry composition may include a polishing accelerator in a range of about 0.1% to about 2% by weight of the composition and/or any range and/or individual value therein, such as, for example, about 0.1% to about 1% or about 0.5% to about 1.5% by weight of the composition.

The selectivity control agent may allow the germanium (Ge) layer and/or the silicon-germanium (SiGe) layer to be polished at a high polishing rate, and may prevent other materials (e.g., silicon, oxide, and/or nitride) from being polished. The selectivity control agent may include a polymer material (e.g., at least one of pyrrolidone-based polymers, glycol-based polymers, oxide-based polymers, acrylate-based polymers, and any combination thereof). In some embodiments, a slurry composition may include a selectivity control agent in a range of about 0.01% to about 1% by weight of the composition and/or any range and/or individual value therein, such as, for example, about 0.1% to about 1% or about 0.1% to about 0.5% by weight of the composition.

In example embodiments, in the case where the polishing process is performed on the silicon (Si) layer, and the germanium (Ge) and/or silicon-germanium (SiGe) layer, the selectivity control agent may include poly(vinylpyrrolidone) (PVP) and polyethylene glycol (PEG). In other example embodiments, in the case where the polishing process is performed on the oxide layer, and the germanium (Ge) and/or silicon-germanium (SiGe) layer, the selectivity control agent may include poly(ethylene oxide) (PEO). In still other example embodiments, in the case where the polishing process is performed on the nitride layer, and the germanium (Ge) and/or silicon-germanium (SiGe) layer, the selectivity control agent may include poly(acrylic acid) (PAA).

In example embodiments, the slurry composition may further include a pH modifier. The pH modifier may control a pH value of the slurry composition. The slurry composition may have the pH value in a range of about 3 to about 7. The pH modifier may include an inorganic acid or an organic acid. For example, the pH modifier may include at least one selected from the group consisting of inorganic acid materials (such as nitric acid, sulfuric acid, hydrochloric acid), organic acid materials (such as acetic acid), and any combination thereof. In some embodiments, a slurry composition may include a pH modifier in an amount sufficient to provide the slurry composition with a pH in a range of about 3 to about 7.

Due to the presence of the oxidizing agent in the slurry composition, the slurry composition may have a high polishing rate on the germanium (Ge) layer and/or the silicon-germanium (SiGe) layer. Changing the selectivity control agent in the slurry composition may allow the germanium (Ge) layer and/or the silicon-germanium (SiGe) layer to have a high polishing rate with respect to other materials, such as, for example, silicon, oxide, and/or nitride.

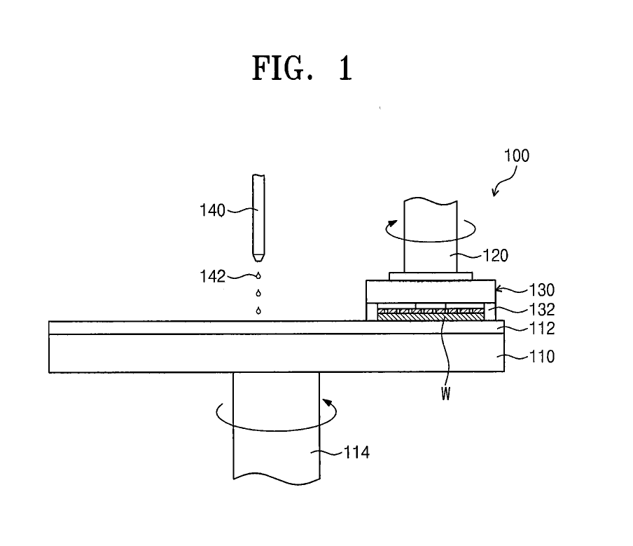

FIG. 1 is a sectional view schematically illustrating a chemical mechanical polishing apparatus according to example embodiments of the present inventive concepts.

Referring to FIG. 1, a chemical mechanical polishing apparatus 100 may include a rotation table 110 attached with a polishing pad 112, a polishing head 130 facing the rotation table 110, a slurry supplying part 140 provided adjacent to the polishing pad 112, and a polishing pad conditioner (not shown).

The rotation table 110 may be shaped like a circular disk. A first driving part 114 may be connected to a bottom of the rotation table 110 to provide a rotating force to the rotation table 110. The polishing pad 112 may be attached on a top surface of the rotation table 110 to polish a to-be-polished surface.

A plurality of pores (not shown) may be formed on a surface of the polishing pad 112. If a slurry composition 142 is supplied during a chemical mechanical polishing (CMP) process on the to-be-polished surface, the slurry composition may be stored in the pores of the polishing pad 112.

The polishing head 130 may hold a wafer W in such a way that the to-be-polished surface of the wafer W faces the rotation table 110. During the CMP process on the wafer W, the polishing head 130 may be pressed in contact with the to-be-polished surface to the polishing pad 112, and the polishing head 130 may be coupled to a second driving part 120 for rotating the wafer W. The polishing head 130 and the rotation table 110 may have different rotating directions from each other. Alternatively, the polishing head 130 and the rotation table 110 may have the same rotating direction as each other.

Although not shown in detail, an air housing may be formed in the polishing head 130 to hold the wafer W and to press the to-be-polished surface of the wafer W onto the polishing pad 112. The air housing may be expanded or contracted to control holding and/or pressing of the wafer W. A retainer ring 132 may be provided on a bottom rim portion of the polishing head 130 to fasten the wafer W. The retainer ring 132 and the wafer W may be stuck to the polishing pad 112, during the CMP process on the wafer W.

The slurry supplying part 140 may supply the slurry composition 142 onto the polishing pad 112. As described above, the slurry composition 142 may include the polishing particle, the oxidizing agent, the polishing accelerator, and/or the selectivity control agent, and for brevity's sake, a detail description thereof will be omitted.

The polishing pad conditioner may be disposed on the polishing pad 112 and may be configured to spray a pressurized vapor onto a surface of the polishing pad 112, thereby allowing a surface state of the polishing pad 112 to be improved.

The following is an example of a CMP process, in which the chemical mechanical polishing apparatus 100 is used to planarize a wafer W.

The polishing head 130 may hold the wafer W in such a way that the to-be-polished surface of the wafer W faces the polishing pad 112. In example embodiments, the to-be-polished surface may include germanium (Ge) and/or silicon-germanium (SiGe). In certain embodiments, the wafer W may further include silicon, oxide, and/or nitride.

The wafer W may be pressed in contact with a rotating top surface of the polishing pad 112. Here, the slurry composition 142 may be supplied from the slurry supplying part 140 onto the polishing head 130. In example embodiments, the slurry composition 142 may be prepared to realize a higher polishing rate of the germanium (Ge) and/or the silicon-germanium (SiGe) with respect to silicon, oxide, and/or nitride. The slurry composition 142 may contain the afore-described material for the slurry composition 142, and for the brevity's sake, a detail description will be omitted.

The slurry composition 142 may be stored in the pores of the polishing pad 112 and the rotation of the polishing pad 112 may allow for the wafer W to be polished chemically and mechanically. By-products may be produced in the polishing of the wafer W, and a mixture of such by-products and the slurry composition 142 may stop up the pores of the polishing pad 112.

The mixture of the by-products and the slurry composition 142 may be taken out from the pores by the conditioner supplied from the polishing pad conditioner and then may be removed from the polishing pad 112 by the rotation of the polishing pad 112.

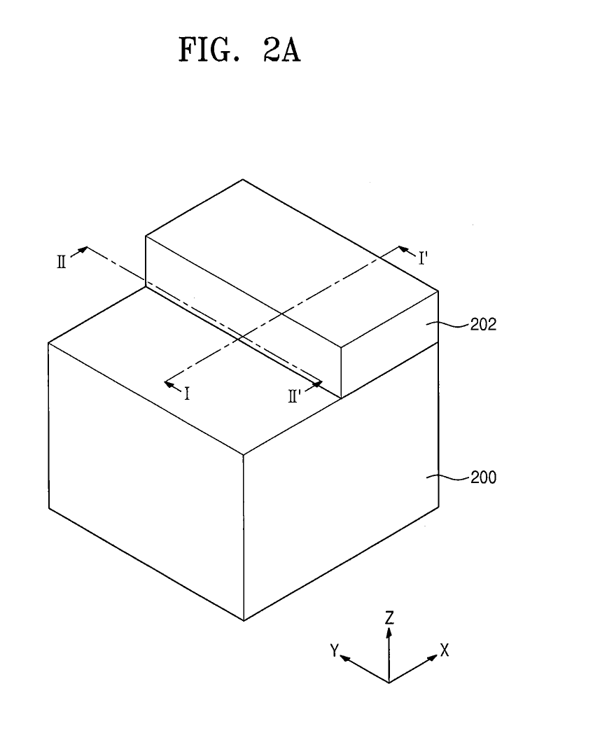

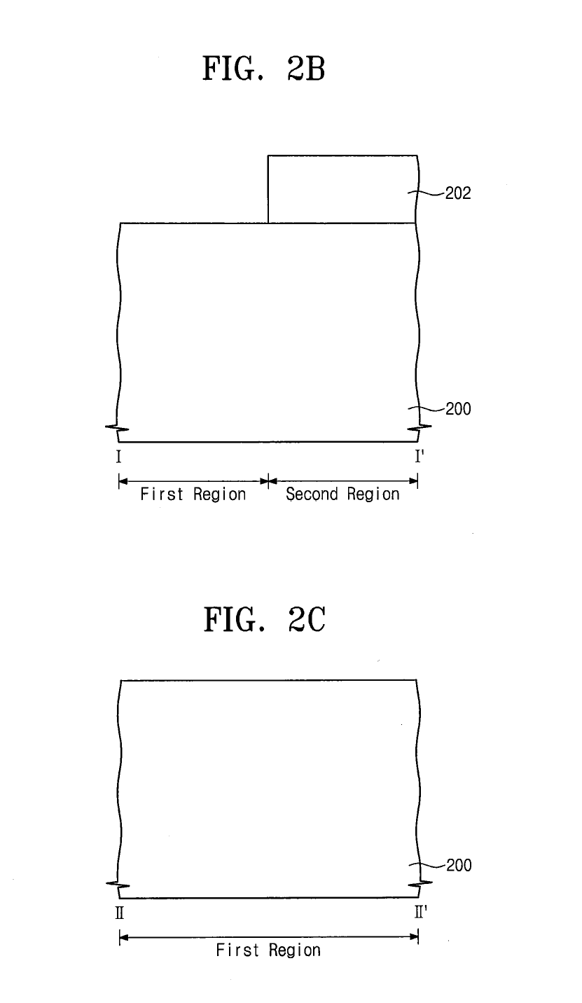

FIGS. 2A through 9A are perspective views illustrating a method of fabricating a semiconductor device according to example embodiments of the present inventive concepts. FIGS. 2B through 9B are sectional views taken along line I-I′ of FIGS. 2A through 9A, respectively, and FIGS. 2C through 9C are sectional views taken along line II-II′ of FIGS. 2A through 9A, respectively.

Referring to FIGS. 2A through 2C, a mask pattern 202 may be formed on a substrate 200 including a first region and a second region. The substrate 200 may be formed of and/or include silicon (Si). The mask pattern 202 may be formed to veil the second region.

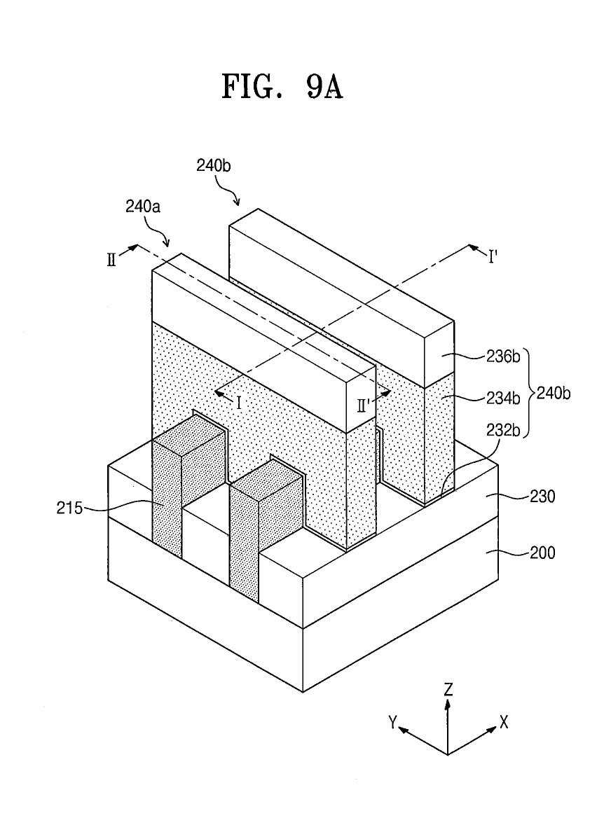

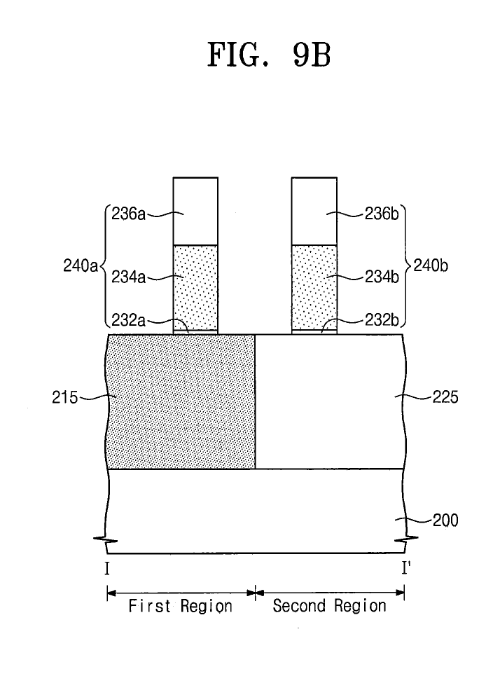

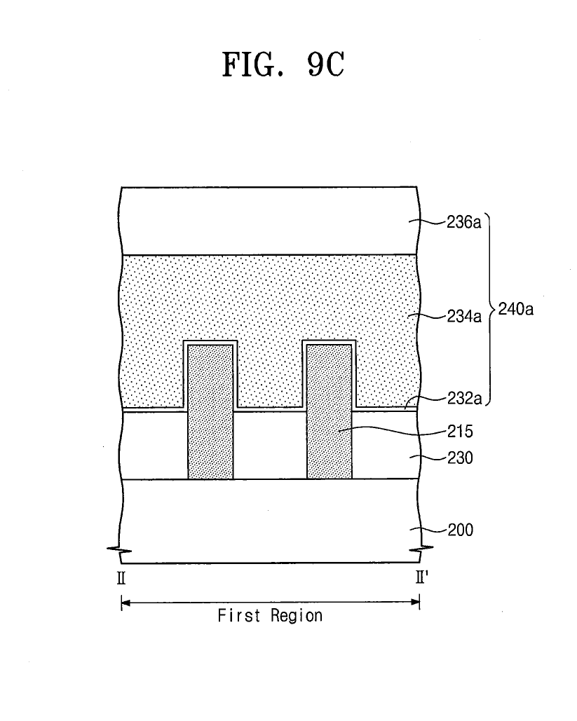

In example embodiments, a PMOS gate structure (e.g., 240a of FIG. 9A) may be formed on the first region, and an NMOS gate structure (e.g., 240b of FIG. 9A) may be formed on the second region.

The mask pattern 202 may include a nitride material (e.g., silicon nitride). Alternatively, the mask pattern 202 may include an oxide material (e.g., silicon oxide).

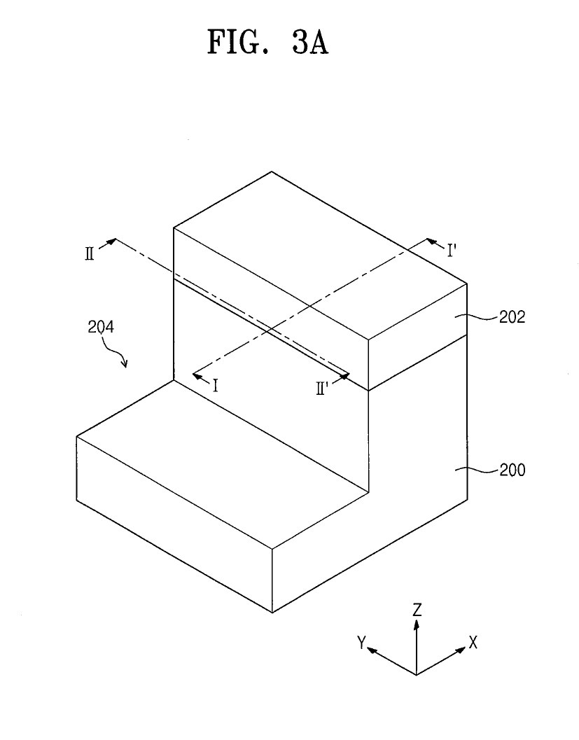

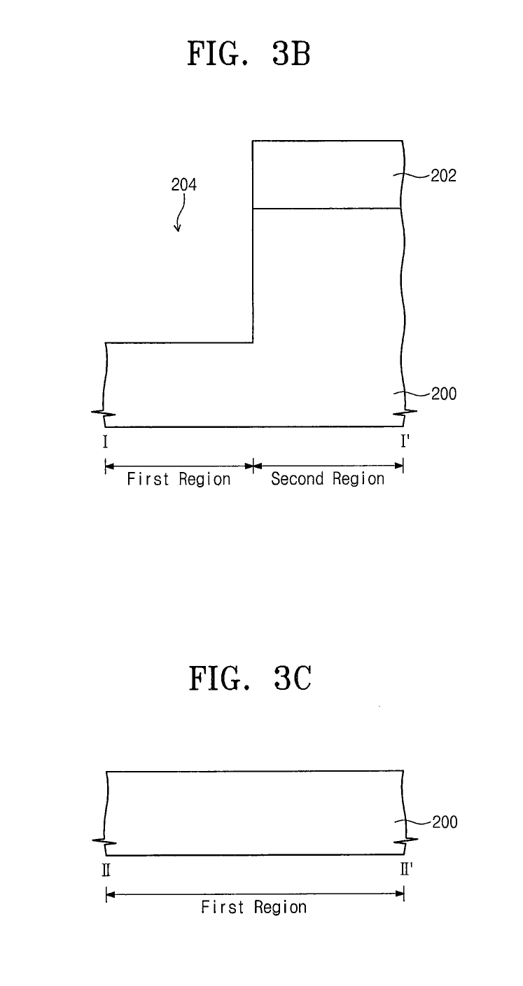

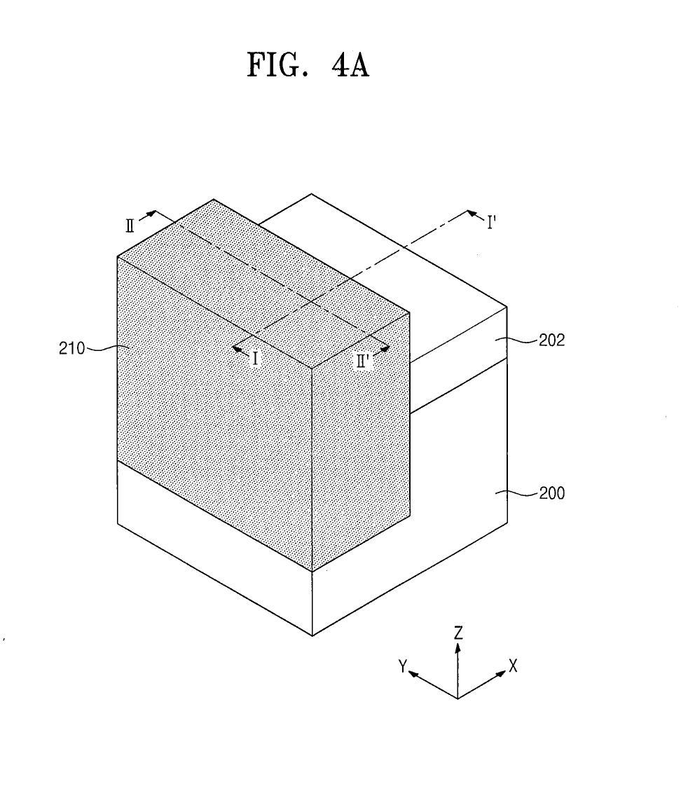

Referring to FIGS. 3A through 3C, the first region may be etched using the mask pattern 202 as an etch mask to form a recess 204.

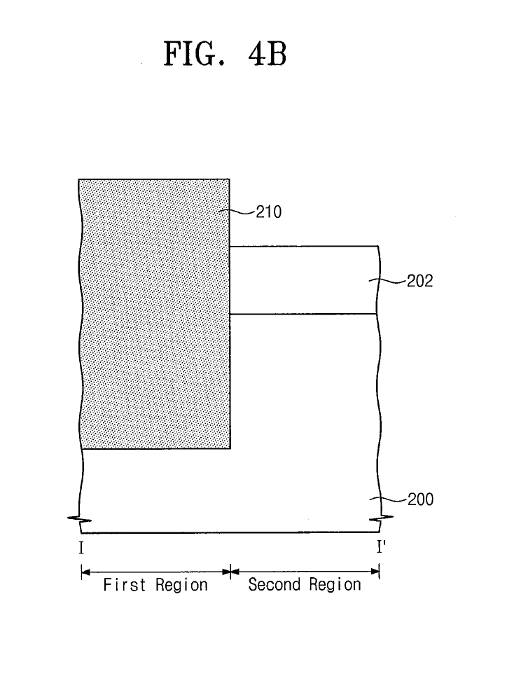

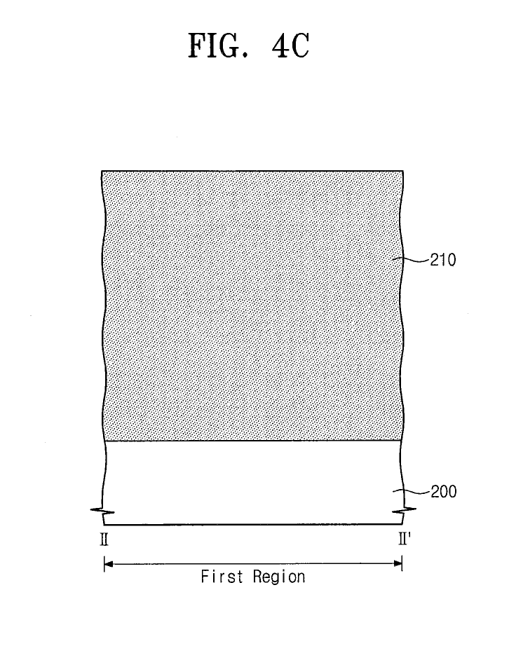

Referring to FIGS. 4A through 4C, the recess 204 may be filled with a germanium-containing material. The first region may be a PMOS region 210 containing germanium. By contrast, the second region may be an NMOS region 220 containing silicon.

According to some aspects of the present inventive concepts, the PMOS region 210 may be formed using a selective-epitaxial growth (SEG) process. During the SEG process, the PMOS region 210 may be formed to have a top surface higher than that of the mask pattern 202.

In example embodiments, at least a portion of the PMOS region 210 may be formed of or contain germanium (Ge) or germanium-silicon (GeSi). The germanium (Ge) or germanium-silicon (GeSi) provided in the PMQS region 210 may contribute to an increase in the charge mobility in a channel region of the PMOS gate structure (e.g., 240a of FIG. 9A), which will be formed in a subsequent process. This may make it possible to improve electric characteristics of a semiconductor device.

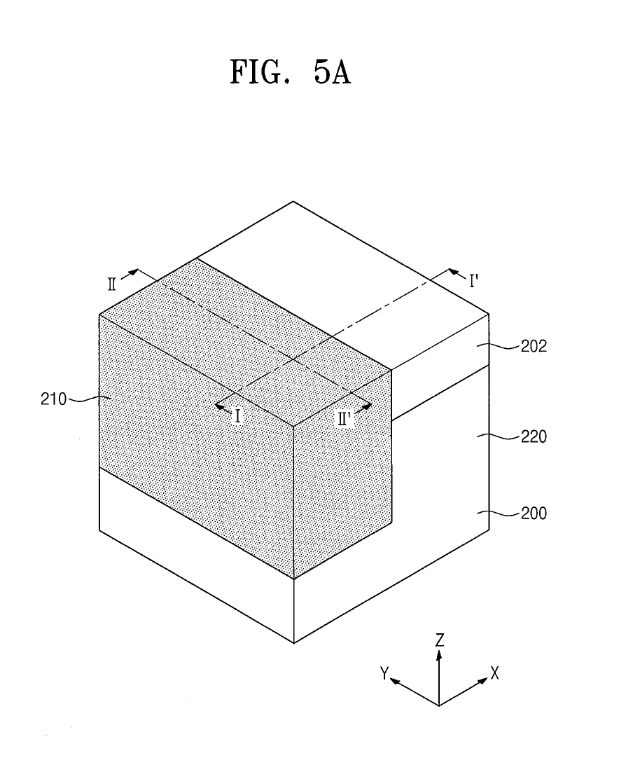

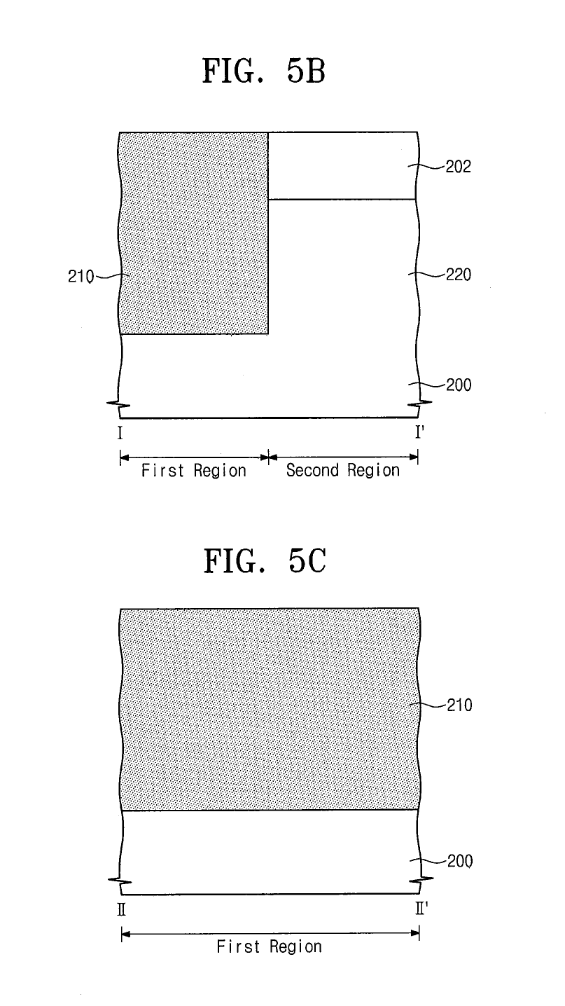

Referring to FIGS. 5A through 5C, the top surface of the PMOS region 210 may be polished in such a way that the PMOS region 210 has the top surface substantially coplanar with that of the mask pattern 202.

The polishing process may be performed using the afore-described slurry composition.

In the case where the mask pattern 202 contains nitride, the slurry composition may be selected to provide a high polishing rate for the germanium (Ge) or germanium-silicon (GeSi) of the PMOS region 210 and a low polishing rate for the nitride of the mask pattern 202. The slurry composition may include PPA serving as the selectivity control agent.

In the case where the mask pattern 202 contains an oxide, the slurry composition may be selected to provide a high polishing rate for the germanium (Ge) and/or germanium-silicon (GeSi) of the PMOS region 210 and a low polishing rate for the oxide of the mask pattern 202. The slurry composition may include PEO as the selectivity control agent.

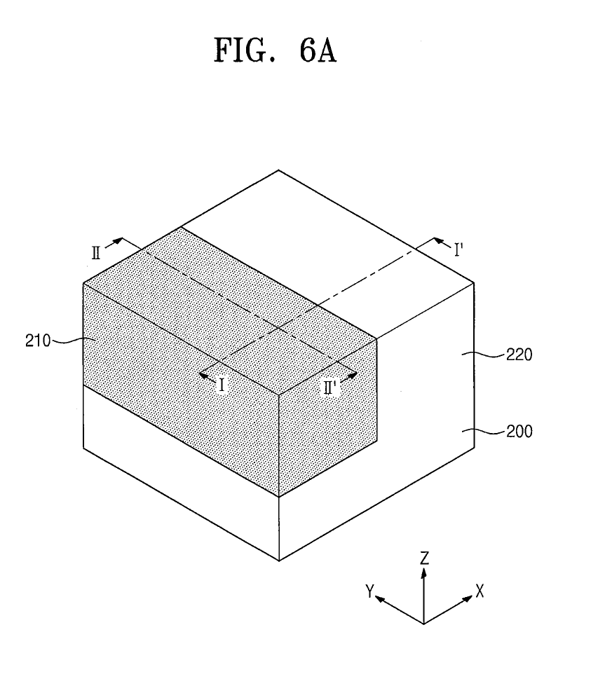

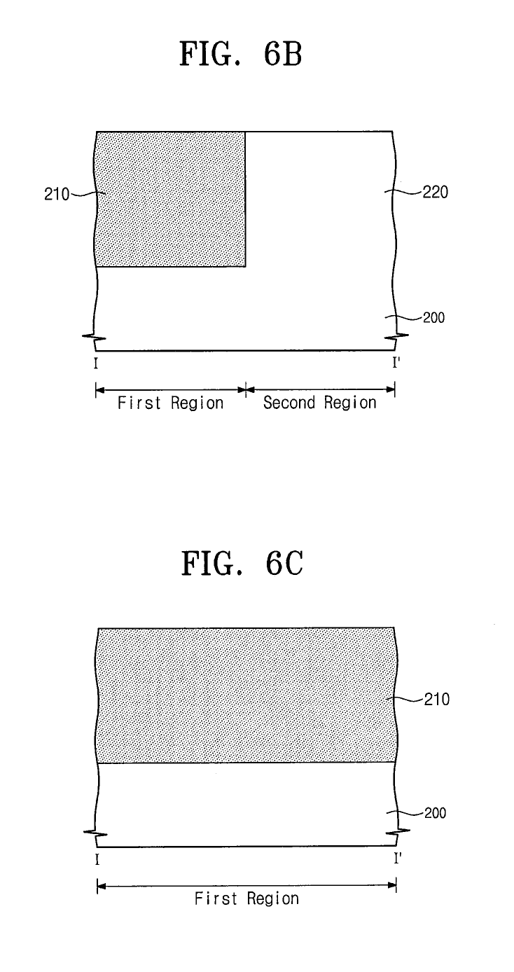

Referring to FIGS. 6A through 6C, the top surface of the PMOS region 210 may be polished in such a way that the PMOS region 210 has the top surface substantially coplanar with that of the NMOS region 220.

In example embodiments, the mask pattern 202 may be removed before the polishing of the top surface of the PMOS region 210. The mask pattern 202 may be removed by a wet etching process or a dry etching process. In other embodiments, the mask pattern 202 may be polished during the process of polishing the top surface of the PMOS region 210.

According to example embodiments of the present inventive concepts, the polishing process may be performed using the afore-described slurry composition. Here, the slurry composition may be selected to provide a high polishing rate for the germanium (Ge) and/or germanium-silicon (GeSi) of the PMOS region 210 and a low polishing rate for the silicon (Si) of the NMOS region 220. The slurry composition may include PVP and/or PEG as the selectivity control agent.

According to example embodiments of the present inventive concepts, by changing the selectivity control agent in the slurry composition, it may be possible to efficiently polish the germanium (Ge) and/or the germanium-silicon (GeSi), while providing a high polishing selectivity with respect to various materials.

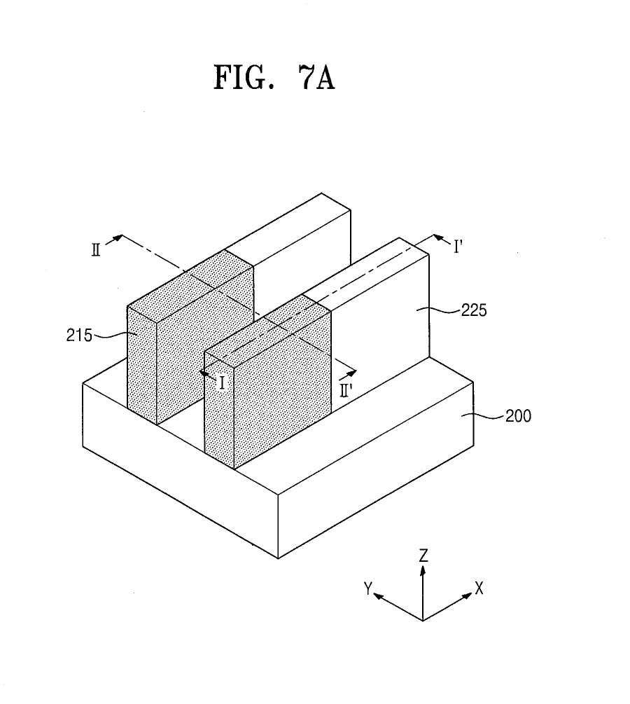

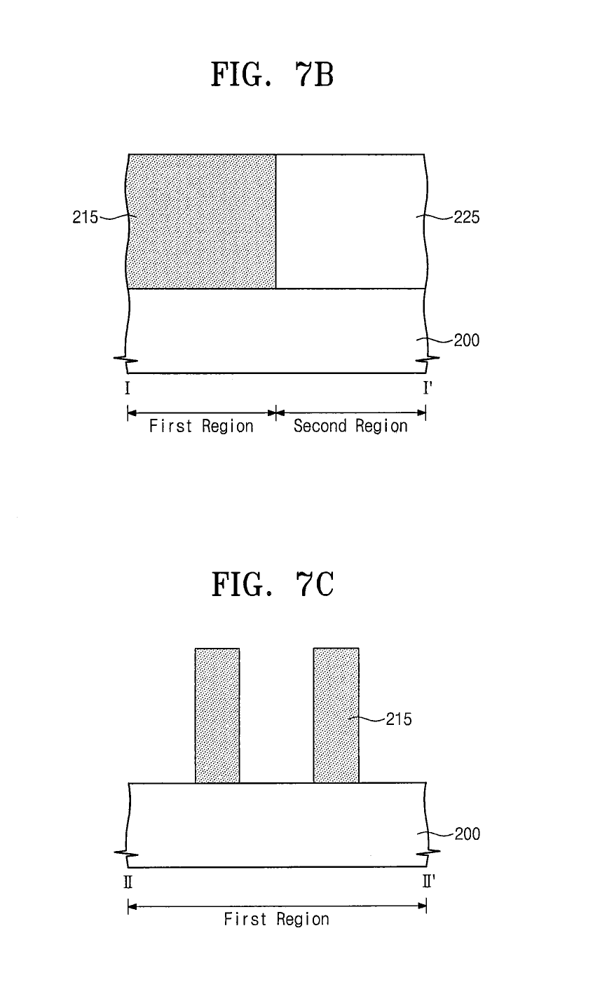

Referring to FIGS. 7A through 7C, the PMQS region 210 and the NMOS region 220 may be etched to form a PMOS active pattern 215 and an NMOS active pattern 225.

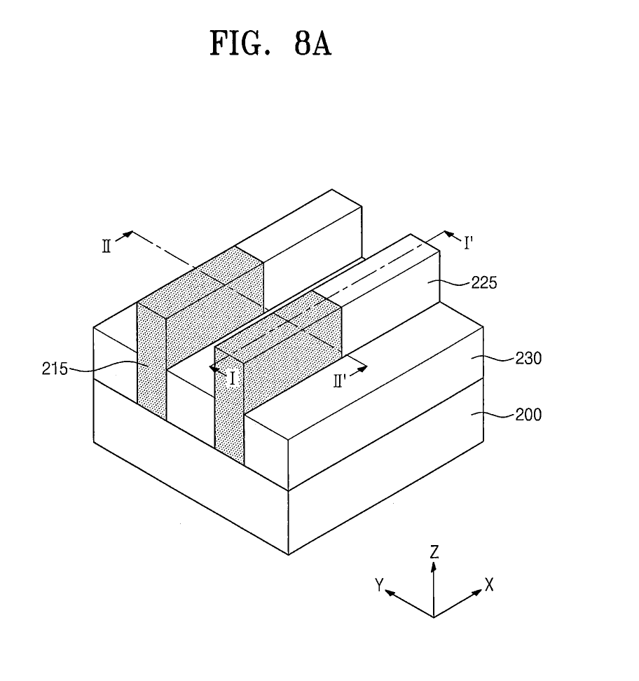

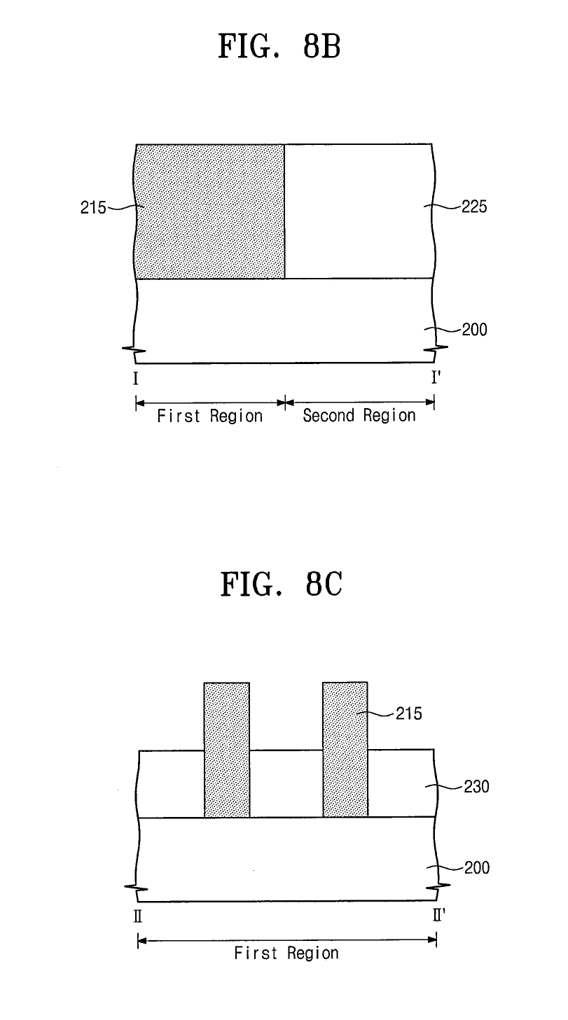

Referring to FIGS. 8A through 8C, a device isolation layer 230 may be formed to fill a gap region between the PMOS and NMOS active patterns 215 and 225. The device isolation layer 230 may be formed to have a top surface lower than those of the PMOS and NMOS active patterns 215 and 225.

Referring to FIGS. 9A through 9C, a PMOS gate structure 240a and an NMOS gate structure 240b may be formed to cross the PMOS and NMOS active patterns 215 and 225, respectively.

For example, the PMOS gate structure 240a may include a gate insulating layer 232a, a PMOS gate electrode 234a, and a capping pattern 236a. The NMOS gate structure 240b may include a gate insulating layer 232b, an NMOS gate electrode 234b, and a capping pattern 236b.

For example, each of the gate insulating layers 232a and 232b of the PMOS and NMOS gate structures 240a and 240b may include a silicon oxide layer or high-k metal oxide layer. Each of the capping patterns 236a and 236b of the PMOS and NMOS gate structures 240a and 240b, respectively, may include a silicon nitride layer.

### Examples

### To Select a pH Range Suitable for a Slurry Composition

### 1. Measuring a Weight Reduction of a Wafer Caused by a Change of pH Value for a Slurry Composition.

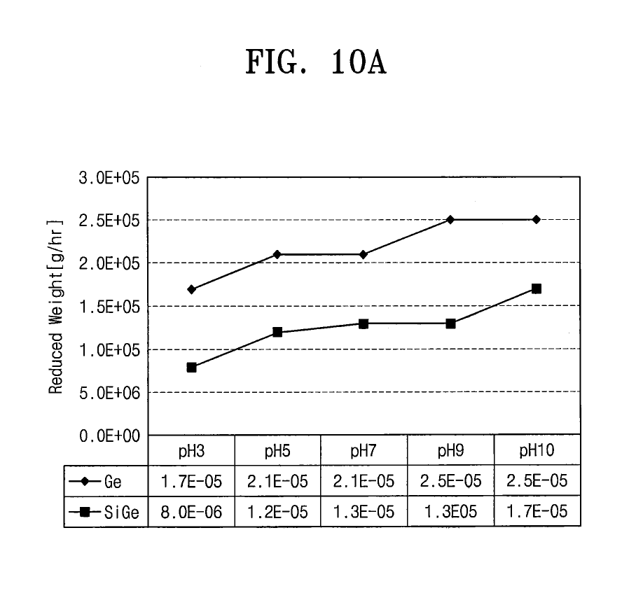

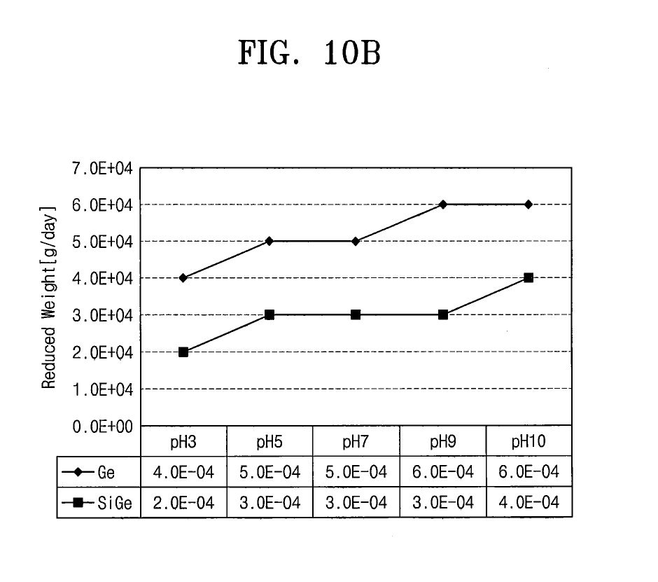

FIGS. 10A and 10B are graphs showing a change in weight for first and second wafers after the first and second wafers were dipped into slurry compositions having different pH values. The first wafer was prepared to have a first layer containing germanium, whereas the second wafer was prepared to have a second layer containing germanium-silicon.

FIGS. 10A and 10B show that the weight reduction of each of the first and second wafers was increased when the pH value of the slurry composition was increased. This means that the higher the pH value of the slurry composition, the more the germanium leaching from the first and second layers.

### 2. Change in Redox Potential According to pH Value of Slurry Composition

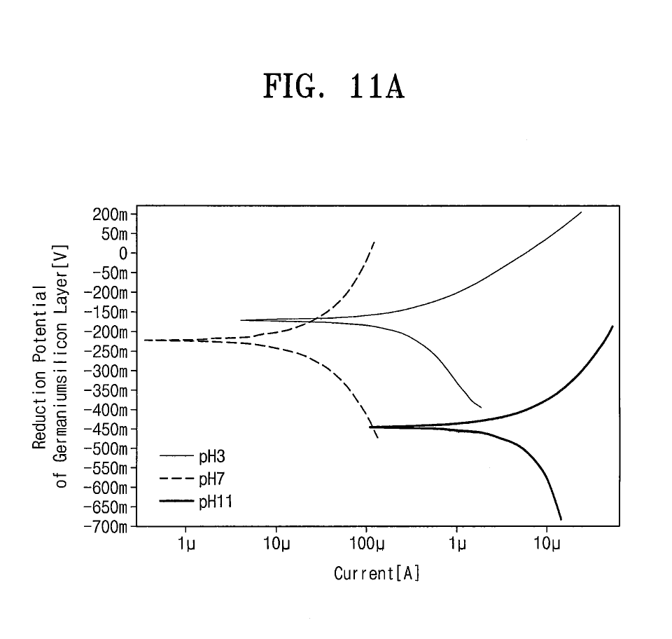

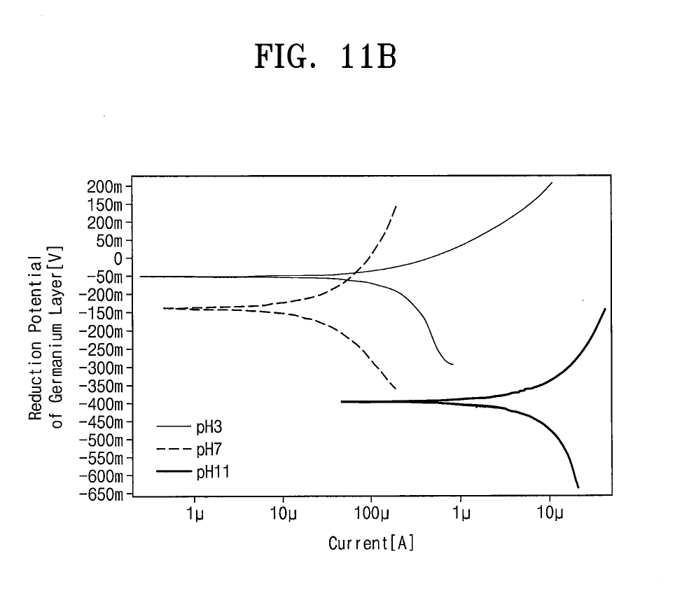

FIGS. 11A and 11B are graphs showing reduction potentials of germanium and germanium-silicon, according to change in pH value for the slurry composition.

Referring to FIGS. 11A and 11B, a germanium layer and a germanium-silicon layer were each dipped into slurry compositions having three different pH values (e.g., pH 3, pH 7, and pH 11), and then, reduction potentials thereof were measured. From FIGS. 11A and 11B, when the slurry composition had a pH of 11 (i.e., was basic), the reduction potential was low, and, without wishing to be bound to any particular theory, this means that corrosion of the germanium layer and the germanium-silicon layer may occur easily. In other words, similar to the experiment of the weight reduction of wafer including germanium or germanium-silicon, the result shows that the slurry composition is preferred to be acidic or neutral (pH 3 and pH 7).

### To Select an Oxidizing Agent

The present experiment was performed to select an oxidizing agent capable of providing a high polishing rate on germanium and germanium-silicon. Table 1 shows polishing rates for germanium and germanium-silicon layers, when the germanium or germanium-silicon layers were polished using various slurry compositions, in which different oxidizing agent materials were contained.

In the experiment, germanium and germanium-silicon layers were polished by slurry compositions having a pH value of 3.5. Each of the slurry compositions was prepared to contain 1 wt % colloidal silica and 0.25 wt % oxidizing agent that was selected from the following materials enumerated in Table 1.

TABLE 1

| | Polishing rate [Å/min] | |
|---|---|---|
| Oxidizing agent | Ge layer | SiGe layer |
| hydrogen peroxide | 877 | 151 |
| chlorine peroxide | 305 | 97 |
| ammonium perchlorate | 408 | 104 |
| sodium chlorite | 1,685 | 610 |
| sodium chlorate | 488 | 102 |
| ferric perchlorate | 705 | 95 |
| ferric nitrate | 500 | 93 |
| potassium nitrate | 650 | 110 |
| ammonium nitrate | 675 | 173 |
| pyridinium chlorochronate | 360 | 73 |
| hypochlorous acid | 50 | 48 |
| sulfonic acid | 75 | 52 |
| carboxylic acid | 106 | 53 |
| citric acid | 114 | 23 |

As shown in Table 1, when the slurry composition was prepared to contain the oxidizing agents, a polishing rate was higher for the germanium layer than for the germanium-silicon layer. In particular, when sodium chlorite was used as the oxidizing agent in the slurry composition, the polishing rates for the germanium and germanium-silicon layers were 1,685 Å/min and 610 Å/min, respectively.

### Contents of Polishing Particle and Oxidizing Agent

The present experiment was performed to quantitatively evaluate dependence of the polishing rate on contents of the polishing particle and the oxidizing agent contained in the slurry composition. In this experiment, slurry compositions using colloidal silica as the polishing particle and sodium chlorite as the oxidizing agent were used to polish the germanium and germanium-silicon layers. Here, as shown in Table 2, slurry compositions containing different amounts of the polishing particle and the oxidizing agent were tested and compared.

TABLE 2

| Amount of | Amount of | | |
|---|---|---|---|
| Oxidizing agent | Polishing particle | Polishing rate [Å/min] | |
| [wt %] | [wt %] | Ge | SiGe |
| 0.25 | 1.0 | 1,685 | 610 |
| 0.4 | 1.0 | 2,323 | 1,200 |
| 0.45 | 1.0 | 2,673 | 1,567 |
| 0.5 | 1.0 | 2,650 | 1,482 |
| 0.45 | 2.0 | 2,705 | 1,584 |
| 0.45 | 2.5 | 2,707 | 1,605 |
| 0.45 | 3.0 | 2,763 | 1,612 |

Table 2 shows that the polishing rate was highest when 0.45 wt % oxidizing agent was used but was substantially unaffected by the amount of the polishing particle. From Table 2, it is possible to minimize a scratch issue on the germanium and the germanium-silicon layers when about 1.0 wt % polishing particle is contained in the slurry composition.

### To Select Polishing Accelerator

The present experiment was performed to select a polishing accelerator suitable for the slurry composition. In this experiment, slurry compositions containing 1 wt % colloidal silica as the polishing particle and 0.45 wt % sodium chlorite as the oxidizing agent were used to polish germanium and germanium-silicon layers. Here, as shown in Table 3, the type and amount of the polishing accelerator present in the slurry composition were varied.

TABLE 3

| Polishing | Amount | Polishing rate [Å/min] | |
|---|---|---|---|
| accelerator | [wt %] | Ge | SiGe |
| None | — | 2,673 | 1,567 |
| carboxylic acid | 0.2 | 2,700 | 1,607 |
| | 0.4 | 2,750 | 1,620 |
| | 0.6 | 2,773 | 1,726 |
| | 0.8 | 2,785 | 1,730 |
| | 1.0 | 2,732 | 1,698 |
| formic acid | 0.2 | 2,753 | 1,673 |
| | 0.4 | 2,840 | 1,720 |
| | 0.6 | 2,935 | 1,850 |
| | 0.8 | 2,950 | 1,845 |
| | 1.0 | 2,897 | 1,793 |
| amino acid | 0.2 | 2,705 | 1,580 |
| | 0.4 | 2,716 | 1,595 |
| | 0.6 | 2,823 | 1,680 |
| | 0.8 | 2,814 | 1,676 |
| | 1.0 | 2,698 | 1,603 |
| sulfuric acid | 0.4 | 950 | 230 |
| nitric acid | 0.4 | 730 | 205 |

Table 3 shows that the polishing rates of the germanium and germanium-silicon layers were higher when an organic acid, such as carboxylic acid, formic acid, and amino acid, was used as the polishing accelerator, than when an inorganic acid, such as sulfuric acid and nitric acid, was used. Without wishing to be bound to any particular theory, this may be because the (-) oxygen group of the carboxyl group has an oxidizing property and serves as an additional oxidizing agent. Further, when carboxylic acid (polishing accelerator) is the organic acid, and the polishing accelerator may be reactionless with the oxidizing agent in the slurry composition. It is possible to improve dispersion of the slurry composition during a process of preparing a slurry composition. According to Table 3, the polishing rate of the germanium and germanium-silicon layers was highest when 0.8 wt % formic acid was used as the polishing accelerator.

### To Select Selectivity Control Agent

The present experiment was performed to select a selectivity control agent for the slurry composition. In the experiment, as described above, various selectivity control agents were used to select a slurry composition having the highest polishing selectivity of the germanium and germanium-silicon layers with respect to the silicon, oxide, and/or nitride layers.

In this experiment, slurry compositions containing 1 wt % colloidal silica as the polishing particle, 0.45 wt % sodium chlorite as the oxidizing agent, and 0.8 wt % formic acid as the polishing accelerator were used to polish a germanium-silicon layer, a silicon layer (e.g., a polysilicon layer), an oxide layer (e.g., a silicon oxide layer), and a nitride layer (e.g., a silicon nitride layer). As shown in Table 4, the type and amount of selectivity control agent present in the slurry composition was varied to test and measure a polishing rate for the germanium silicon layer with respect to the silicon layer, the oxide layer, and the nitride layer.

TABLE 4

| Selectivity | Amount | Polishing rate [Å/min] | | | | |
|---|---|---|---|---|---|---|
| control agent | [wt %] | SiGe | Si(poly Si) | SiO₂ | SiN | Remark |
| None | — | 1,850 | 600 | 650 | 530 | — |
| PEG | 0.1 | 1,520 | 45 | 75 | 287 | Si stop |
| | 0.2 | 1,450 | 20 | 39 | — | |
| | 0.3 | 1,432 | 21 | 37 | — | |
| PAA | 0.1 | 1,490 | 315 | 286 | 32 | SiN stop |
| | 0.2 | 1,453 | — | — | 21 | |
| | 0.3 | 1,420 | — | — | 19 | |
| PEO | 0.1 | 1,500 | 82 | 46 | 250 | SiO₂ stop |
| | 0.2 | 1,485 | 46 | 21 | — | |
| | 0.3 | 1,453 | 37 | 20 | — | |
| PVP | 0.1 | 1,480 | 20 | 67 | 310 | Si stop |
| | 0.2 | 1,400 | 14 | 39 | — | |
| | 0.3 | 1,340 | 11 | 27 | — | |

According to Table 4, when a slurry composition containing PVP or PEG was used, the germanium-silicon layer had a high polishing rate and the silicon (e.g., poly Si) layer had a low polishing rate. This means that when a silicon layer is formed under a germanium-silicon layer, the silicon layer may be used as a layer for detecting a polishing end point.

When a slurry composition containing PEO was used, the germanium-silicon layer had a high polishing rate and the oxide (e.g., SiO₂) layer had a low polishing rate. This means that when an oxide layer is formed under a germanium-silicon layer, the oxide layer may be used as a layer for detecting a polishing end point.

When a slurry composition containing PAA was used, the germanium-silicon layer had a high polishing rate and the nitride (e.g., Si₃N₄) layer had a low polishing rate. This means that when a nitride layer is formed under a germanium-silicon layer, the nitride layer may be used as a layer for detecting a polishing end point.

### To Measure Roughness of Silicon-Germanium Layer Before and After Polishing

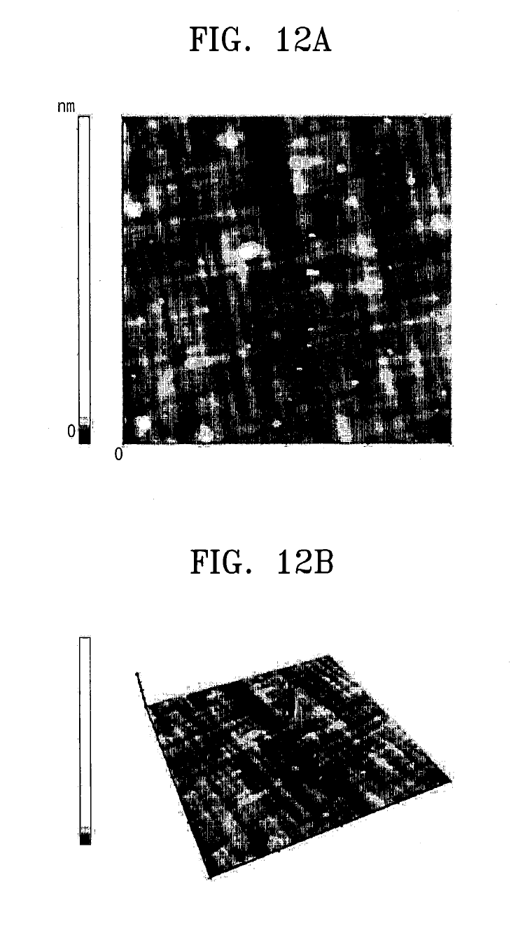

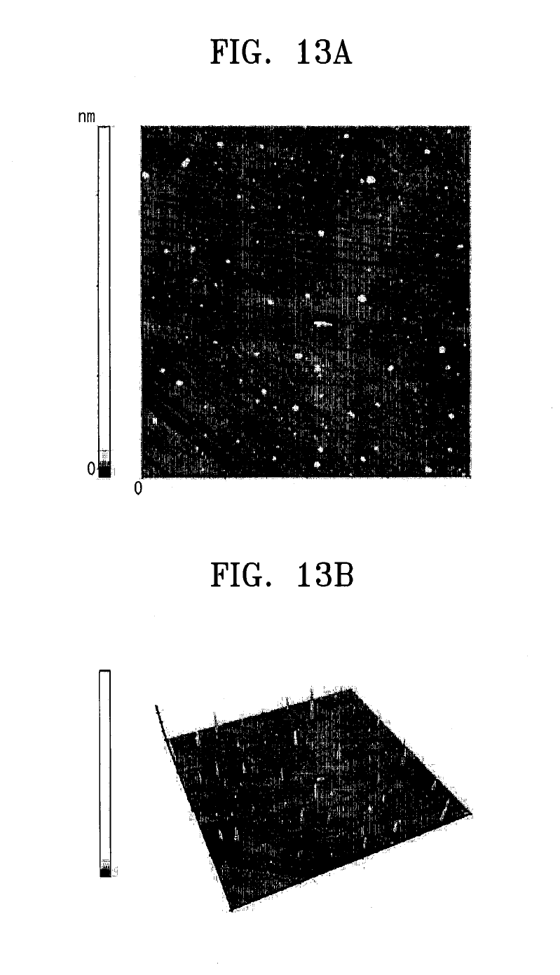

FIGS. 12A and 12B are images showing surface roughness of a wafer on which a silicon-germanium layer was formed, and FIGS. 13A and 13B are images showing surface roughness of a wafer on which a polishing process has been performed using a slurry composition according to example embodiments of the present inventive concepts.

The wafer surface roughness shown in FIGS. 12A, 12B, 13A, and 13B was measured by an atomic force microscope (AFM). The polishing process was a chemical mechanical polishing process in which the slurry composition according to example embodiments of the present inventive concepts was used.

Table 5 shows values of wafer surface roughness measured by the AFM, before and after the polishing process of the silicon-germanium layer.

TABLE 5

| | Rpv [nm] | Rq [nm] | Ra [nm] | Rz [nm] |
|---|---|---|---|---|
| Before CMP | 86.879 | 1.61 | 0.834 | 50.948 |
| After CMP | 38.409 | 0.864 | 0.282 | 29.224 |

As shown in FIGS. 13A and 13B, deterioration of the surface of the wafer was not found after the chemical mechanical polishing process. Referring to Table 5 and comparing FIGS. 12A and 12B to FIGS. 13A and 13B, it can be found that the wafer surface roughness was improved after the polishing process in which a slurry composition according to example embodiments of the present inventive concepts was used.

According to example embodiments of the present inventive concepts, a slurry composition may include an oxidizing agent capable of providing a high polishing rate to a germanium (Ge) layer and/or a silicon-germanium (SiGe) layer. In some embodiments, by changing the type of a selectivity control agent present in a slurry composition, it may be possible to polish a germanium (Ge) layer and/or a silicon-germanium (SiGe) layer at a higher polishing rate than those of other materials, such as silicon, oxide, and/or nitride.

While example embodiments of the present inventive concepts have been particularly shown and described herein, it will be understood by one of ordinary skill in the art that variations in form and detail may be made therein without departing from the spirit and scope of the attached claims.

What is claimed is:

1. A slurry composition for polishing a germanium-containing layer, comprising:
a polishing particle;
an oxidizing agent comprising at least one selected from the group consisting of superoxide, dioxygenyl, ozone, ozonide, chlorite, chlorate, perchlorate, halogen compounds, nitric acid, nitrate, hypochlorite, hypohalite, and peroxide;
a polishing accelerator; and
a selectivity control agent.

2. The slurry composition of claim 1, wherein the polishing particle comprises at least one of silica (SiO₂), ceria (CeO₂), and aluminum (Al₂O₃).

3. The slurry composition of claim 1, wherein the polishing particle has a size in a range of 30 nm to 80 nm.

4. The slurry composition of claim 1, wherein the polishing accelerator comprises an organic acid.

5. The slurry composition of claim 4, wherein the polishing accelerator comprises at least one selected the group consisting of acetic acid, citric acid, formic acid, gluconic acid, lactic acid, oxalic acid, tartaric acid, and carboxylic acid.

6. The slurry composition of claim 1, wherein the selectivity control agent comprises a material allowing the germanium-containing layer to have a higher polishing rate than that of a layer containing at least one of silicon, oxide, and nitride.

7. The slurry composition of claim 6, wherein the selectivity control agent comprises at least one of pyrrolid one-based polymers, glycol-based polymers, oxide-based polymers, and acrylate-based polymers.

8. The slurry composition of claim 6, wherein the selectivity control agent comprises at least one of poly(vinylpyrrolidone) (PVP) and polyethylene glycol (PEG), when the germanium-containing layer is polished along with a silicon-containing layer.

9. The slurry composition of claim 6, wherein the selectivity control agent comprises poly(ethylene oxide) (PEO), when the germanium-containing layer is polished along with an oxide-containing layer.

10. The slurry composition of claim 6, wherein the selectivity control agent comprises poly(acrylic acid) (PAA), when the germanium-containing layer is polished along with a nitride-containing layer.

11. The slurry composition of claim 1, further comprising a pH modifier.

12. The slurry composition of claim 11, wherein the slurry composition has a pH value in a range of 3 to 7.

13. The slurry composition of claim 11, wherein the pH modifier comprises at least one of nitric acid, sulfuric acid, hydrochloric acid, and acetic acid.

14. A method of fabricating a semiconductor device, comprising:
forming a silicon-containing NMOS region and a germanium-containing PMOS region on a silicon-containing substrate; and
polishing the germanium-containing PMOS region using the slurry composition of claim 1 to have a top surface coplanar with that of the silicon-containing NMOS region.

15. The method of claim 14, wherein the forming of the silicon-containing NMOS region and the germanium-containing PMOS region on the silicon-containing substrate comprises:
forming a mask pattern on a silicon-containing initial substrate;
etching the silicon-containing initial substrate using the mask pattern to form a recess; and
forming the germanium-containing PMOS region to fill the recess.

16. A composition comprising:
a polishing particle;
an oxidizing agent;
a polishing accelerator; and
a selectivity control agent,
wherein the composition is in the form of a slurry and has a pH value in a range of 3 to 7.

17. The composition of claim 16, wherein the polishing particle has a size in a range of 30 nm to 80 nm.

18. The composition of claim 16, wherein the polishing accelerator comprises an organic acid.

19. The composition of claim 16, wherein the selectivity control agent is selected from the group consisting of poly(vinylpyrrolidone) (PVP), polyethylene glycol, (PEG), poly(ethylene oxide) (PEO), poly(acrylic acid) (PAA), and any combination thereof.

20. The composition of claim 16, wherein the composition, when used in a polishing process, provides a polishing rate for a germanium-containing layer in a range of about 1,600 Å/min to about 3,000 Å/min and/or a polishing rate for a layer containing silicon, oxide, and/or nitride in a range of about 10 Å/min to about 50 Å/min.
